(19) United States
(12) Patent Application Publication
(10) Pub. No.: US 2020/0292749 A1
(43) Pub. Date: Sep. 17, 2020

(54) Backlight Module and Electronic Device

(71) Applicant: GUANGDONG OPPO MOBILE TELECOMMUNICATIONS CORP., LTD., Dongguan (CN)

(72) Inventor: Zhibin Ouyang, Dongguan (CN)

(21) Appl. No.: 16/889,753

(22) Filed: Jun. 1, 2020

Related U.S. Application Data
(63) Continuation of application No. PCT/CN2018/120028, filed on Dec. 10, 2018.

(30) Foreign Application Priority Data
Jan. 31, 2018 (CN) 201810106256.9
Jan. 31, 2018 (CN) 201820181747.5

(51) Int. Cl. F21V 8/00; F21V 17/10; H05K 1/02

(52) U.S. Cl. CPC G02B 6/0088; F21V 17/10; F21Y 2115/10; G02B 6/0028; H05K 1/028; G02B 6/0031

(57) ABSTRACT

A backlight module and an electronic device are provided. When an optical assembly is assembled, a first positioning portion and a second positioning portion are cooperatively positioned to receive the optical assembly within accommodating spaces via the backlight module, such that a distance between a light guide plate and a backlight source is less than or equal to a threshold value, preventing a circumstance from occurring during assembly in which the distance between the light guide plate and the backlight source is excessively large, causing the light guide plate to not be able to completely receive light emitted by the backlight source.

### CROSS-REFERENCE TO RELATED APPLICATION(S)

The present application is a continuation application of International (PCT) Patent Application No. PCT/CN2018/120028, filed on Dec. 10, 2018, which claims priority to Chinese Patent Application No. 201810106256.9, filed on Jan. 31, 2018 and Chinese Patent Application No. 201820181747.5, filed on Jan. 31, 2018, the entire contents of all of which are hereby incorporated by reference in their entireties.

### TECHNICAL FIELD

The present disclosure relates to the field of electronic devices, and in particular to a backlight module and an electronic device.

### BACKGROUND

A backlight module of an electronic device may include an optical assembly and a backlight source. During assembling, a distance between a light guide plate of the optical assembly and the backlight source may be too large, such that the light guide plate may not be able to receive light emitted from the backlight source completely, and a backlight effect of the light guide plate may be reduced.

### SUMMARY

According to a first aspect of the present disclosure, a backlight module is provided and includes: a back frame, an optical assembly, a backlight source, and a positioning member. The back frame includes a side wall and a bottom wall, and the side wall and the bottom wall are connected to each other and define a receiving space. The optical assembly is arranged on the bottom wall and received in the receiving space, and includes a light guide plate. The light guide plate defines a recess. The backlight source includes a lamp and a flexible circuit board and is arranged on a side of the light guide plate close to the side wall. The positioning member is arranged to connect to the back frame and at least partially received in the receiving space. The positioning member comprises a positioning portion. The positioning portion is engaged into the recess, such that a distance between the light guide plate and the backlight source is less than or equal to a threshold. The positioning portion is arranged to protrude from the positioning member, and a protruding direction of the positioning portion is parallel to an extending direction of the backlight source.

According to a second aspect of the present disclosure, a backlight module is provided and includes: a back frame, an optical assembly, a backlight source, and a positioning member. The back frame includes a side wall and a bottom wall, and the side wall and the bottom wall are connected to each other and define a receiving space. The optical assembly is arranged on the bottom wall and received in the receiving space, and includes a light guide plate. The light guide plate defines a recess. The backlight source comprises a lamp and a flexible circuit board. The lamp is arranged on and extends along a side of the light guide plate close to the side wall. The positioning member is arranged to connect to the back frame and at least partially received in the receiving space. The positioning member comprises a positioning portion. The f positioning portion is engaged into the recess, such that a distance between the light guide plate and the backlight source is less than or equal to a threshold.

According to a third aspect of the present disclosure, an electronic device is provided and includes a display module and a backlight module. The display module is arranged to stack above the backlight module, and the backlight module includes: a back frame, an optical assembly, a backlight source, and a positioning member. The back frame includes a side wall and a bottom wall, and the side wall and the bottom wall are connected to each other and define a receiving space. The optical assembly is arranged on the bottom wall and received in the receiving space, and includes a light guide plate. The light guide plate defines a recess. The backlight source is arranged on a side of the light guide plate close to the side wall. The positioning member is arranged to connect to the back frame and at least partially received in the receiving space. The positioning member comprises a positioning portion, and the positioning portion is engaged into the recess, enabling a distance between the light guide plate and the backlight source to be less than or equal to a threshold. The threshold is less than or equal to 0.1 mm.

### BRIEF DESCRIPTION OF DRAWINGS

In order to illustrate technical solutions of embodiments of the present disclosure in details, drawings required for illustrating the embodiments will be described in brief. Obviously, the following drawings illustrate only some embodiments of the present disclosure, and to any one of skill in the related art, other drawings may be obtained based on the following drawings without any creative work.

FIG. 1 is a structural schematic view of a backlight module according to a first embodiment of the present disclosure.

FIG. 2 is a schematic view of a cross section of the embodiment shown in FIG. 1, taken along a line of II-II.

FIG. 3 is a schematic view of a cross section of the embodiment shown in FIG. 1, taken along a line of

FIG. 4 is an assembly schematic view of a light-shielding tape and a back frame according to an embodiment of the present disclosure.

FIG. 5 is a cross-sectional view of a backlight module according to a second embodiment of the present disclosure.

FIG. 6 is a schematic view of the back frame shown in FIG. 5 of the present disclosure.

FIG. 7 is a schematic view of an electronic device according to an embodiment of the present disclosure.

### DETAILED DESCRIPTION

The present disclosure will be further illustrated in details by referring to drawings and embodiments. Specifically, following embodiments are for the purpose of illustrating the present disclosure, but do not limit the scope of the present disclosure. Similarly, the following embodiments are only a part of, but not all of, the embodiments of the present disclosure. Any other embodiment obtained by any one of skill in the art without performing creative work should be within the scope of the present disclosure.

The term “embodiment” indicates that specific characteristics, structures, or properties described in an embodiment may be included in at least one embodiment of the present disclosure. The expression “embodiment” appearing in various sections of the present specification may not indicate a same embodiment, and may not indicate an independent or alternative embodiment mutually exclusive of other embodiments. Any one of skill in the art should implicitly and explicitly understand that the embodiments described herein can be combined with other embodiments.

According to a first aspect of the present disclosure, a backlight module is provided and includes: a back frame, an optical assembly, a backlight source, and a positioning member. The back frame includes a side wall and a bottom wall, and the side wall and the bottom wall are connected to each other and define a receiving space. The optical assembly is arranged on the bottom wall and received in the receiving space, and includes a light guide plate. The light guide plate defines a recess. The backlight source includes an array of light emitting elements and a flexible circuit board, wherein the light emitting elements are arranged on a side of the light guide plate close to the side wall along a row direction and a column direction, the row direction is parallel to an extending direction of the side of the light guide plate arranged with the light emitting elements. The positioning member is arranged to connect to the back frame and at least partially received in the receiving space. The positioning member comprises a positioning portion. The positioning portion is engaged into the recess, such that a distance between the light guide plate and the backlight source is less than or equal to a threshold. The positioning portion is arranged to protrude from the positioning member, and a protruding direction of the positioning portion is parallel to the row direction of the light emitting elements.

In some embodiments, the positioning member includes a body portion and an extension portion. The body portion is connected to the back frame, and the extension portion is arranged to extend from the body portion towards the receiving space. The positioning portion is arranged to perpendicularly protrude from an end of the extension portion away from the body portion.

In some embodiments, At least two side walls are arranged and connected to each other. The body portion is arranged at a position at which the at least two side walls connect to each other, and the extension portion is arranged to extend from the body portion towards a position between another side of the light guide plate without the backlight source arranged and at least one of the at least two side walls.

According to a second aspect of the present disclosure, a backlight module is provided and includes: a back frame, an optical assembly, a backlight source, and a positioning member. The back frame includes a side wall and a bottom wall, and the side wall and the bottom wall are connected to each other and define a receiving space. The optical assembly is arranged on the bottom wall and received in the receiving space, and includes a light guide plate. The light guide plate defines a recess. The backlight source comprises a lamp and a flexible circuit board. The lamp is arranged on and extends along a side of the light guide plate close to the side wall. The positioning member is arranged to connect to the back frame and at least partially received in the receiving space. The positioning member comprises a positioning portion. The f positioning portion is engaged into the recess, and an extending direction of the positioning portion is parallel to an extending direction of the lamp, such that a distance between the light guide plate and the backlight source is less than or equal to a threshold.

In some embodiments, the positioning member includes a body portion and an extension portion. The body portion is arranged to connect to the back frame, and the extension portion is arranged to extend from the body portion towards the receiving space. The second positioning portion is arranged on the extension portion.

In some embodiments, at least two side walls are arranged and connected to each other. The body portion is arranged at a position at which the at least two side walls are connected to each other, and the extension portion is arranged to extend from the body portion towards a position between the light guide plate and at least one of the at least two side walls.

In some embodiment, the lamp is a plurality of light emitting elements arranged in a row, the positioning portion is arranged to perpendicularly protrude from an end of the extension portion away from the body portion, and a protruding direction of the positioning portion is parallel to a direction of the row.

In some embodiments, the back frame further includes a top wall. The top wall and an end of the side wall away from the bottom wall are connected to each other. The top wall, the side wall, and the bottom wall cooperatively define the receiving space. The positioning member is arranged on a side of the top wall away from the receiving space and is arranged to align with the top wall.

In some embodiments, the threshold is less than or equal to 0.1 mm.

In some embodiments, the flexible circuit board is adhered to a side of the lamp

(YB:01050581.DOCX away from the light guide plate.

In some embodiments, the light guide plate includes a light incidence surface and a light emitting surface. The lamp is arranged on the light incidence surface of the light guide plate and at an optimized position for light emitting.

In some embodiments, the optimized position for light emitting is an optimized position of the lamp in height and in distance relative to the light guide plate, such that emitted light may be completely received by the light guide plate.

In some embodiments, a first adhesion member is arranged between the lamp and the bottom wall, and the lamp is adhered to the bottom wall via the first adhesion member, such that the lamp is arranged at the optimized position in height relative to the light guide plate by providing the first adhesion member in an appropriate thickness.

In some embodiments, a second adhesion member is arranged between the lamp and the side wall, and the lamp is adhered to the side wall via the second adhesion member, such that the lamp is arranged at the optimized position in distance relative to the light guide plate by providing the second adhesion member in an appropriate thickness.

In some embodiments, the receiving space includes a first space and a second space communicating with each other, the first space and the second space are sequentially defined along a direction facing towards the side wall. The optical assembly is received in the first space. An area of a cross section of the second space taken along the direction facing towards the side wall is greater than that of the first space taken along the facing towards the side wall, and the lamp is received in the second space.

In some embodiments, the optical assembly further includes an optical film assembly arranged on the light emitting surface of the light guide plate. The backlight module further includes a light-shielding tape, and the light-shielding tape is arranged on a side of the top wall away from the receiving space and adhered to the top wall and the optical film assembly.

In some embodiments, the light-shielding tape is further arranged on a side of the side wall away from the receiving space and adhered to the side wall.

According to a third aspect of the present disclosure, an electronic device is provided and includes a display module and a backlight module. The display module is arranged to stack above the backlight module, and the backlight module includes: a back frame, an optical assembly, a backlight source, and a positioning member. The back frame includes a side wall and a bottom wall, and the side wall and the bottom wall are connected to each other and define a receiving space. The optical assembly is arranged on the bottom wall and received in the receiving space, and includes a light guide plate. The light guide plate defines a recess. The backlight source is arranged on a side of the light guide plate close to the side wall. The positioning member is arranged to connect to the back frame and at least partially received in the receiving space. The positioning member comprises a positioning portion, and the positioning portion is engaged into the recess, enabling a distance between the light guide plate and the backlight source to be less than or equal to a threshold. The threshold is less than or equal to 0.1 mm.

In some embodiments, the positioning member further includes a body portion and an extension portion, the body portion is connected to the back frame, and the extension portion is arranged to extend from the body portion towards a position between another side of the light guide plate without the backlight source arranged and the side wall.

In some embodiments, the backlight source includes a lamp extending along the side of the light guide plate close to the side wall, the positioning portion is arranged to perpendicularly protrude from an end of the extension portion away from the body portion, and a protruding direction of the positioning portion is parallel to an extending direction of the lamp.

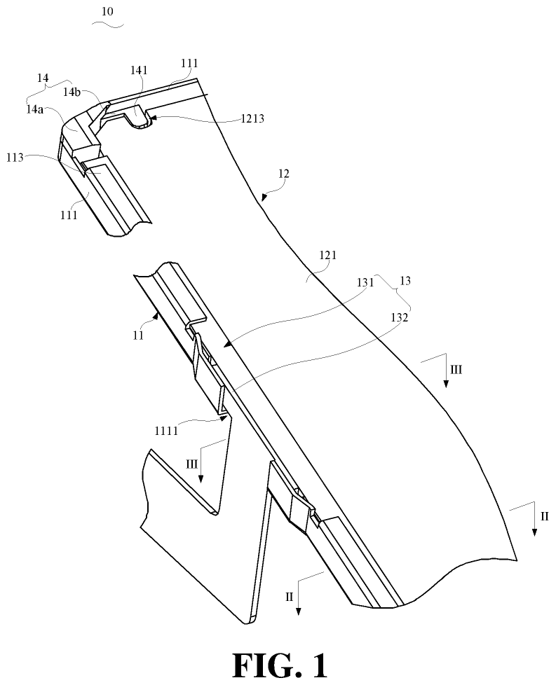

As shown in FIG. 1, a structural schematic view of a backlight module 10 according to a first embodiment is provided. The backlight module 10 of the present embodiment may include a back frame 11, an optical assembly 12, a backlight source 13, and a positioning member 14.

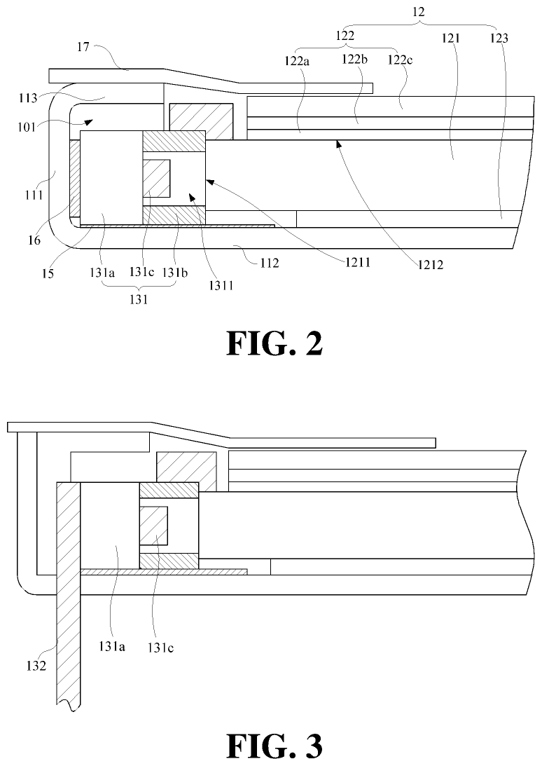

As shown in FIG. 1 and FIG. 2, the back frame 11 may include a side wall 111 and a bottom wall 112, and the side wall 111 and the bottom wall 112 may be bent to connect to each other and define a receiving space 101.

Alternatively, at least two side walls 111 may be arranged, and the at least two side walls 111 may be bent to connect to each other.

Alternatively, the back frame 11 may further include a top wall 113. The top wall 113 and an end of the side wall 111 away from the bottom wall 112 may be bent to connect to each other. The top wall 113, the side wall 111, and the bottom wall 112 may cooperatively define the receiving space 101. The top wall 113 may be arranged to carry a display module when the backlight module 10 is assembled with the display module of an electronic device.

Further, as shown in FIG. 1, the back frame 11 may define an opening 1111 communicating with the receiving space 101.

Alternatively, the back frame 11 may be a metal back frame.

The optical assembly 12 may be received in the receiving space 101 and arranged on the bottom wall 112.

The optical assembly 12 may include a light guide plate 121. The light guide plate 121 may include a light incidence surface 1211 and a light emitting surface 1212. The light incidence surface 1211 may be a surface of the light guide plate 121 close to the side wall 111, and the light emitting surface 1212 may be a surface of the light guide plate 121 away from the bottom wall 112. As shown in FIG. 1, the light guide plate 121 may be arranged with a first positioning portion 1213.

Alternatively, the first positioning portion 1213 may be a recess.

Further, the optical assembly 12 may further include an optical film assembly 122 and a reflection sheet 123. The optical film assembly 122 may be arranged on the light guide plate 121 and may specifically be on the light emitting surface 1212 of the light guide plate 121. The reflection sheet 123 may be arranged on the bottom wall 112, facing towards a side of the light guide plate 121 away from the light emitting surface 1212.

The optical film assembly 122 may include a diffusion film 122a, a lower transmission increasing film 122b, and an upper transmission increasing film 122c sequentially stacked along a direction away from the light guide plate 121.

The backlight source 13 may be arranged on a side of the light guide plate 121 close to the side wall 111. Specifically, the backlight source 13 may be arranged on a side of the light guide plate 121 close to one of the at least two side walls 111.

In the present embodiment, the backlight source 13 may include a lamp 131, serving as a light source, and a flexible circuit board 132.

The lamp 131 may be arranged on the side of the light guide plate 121 close to the side wall 111. Specifically, the lamp 131 may be arranged on the light incidence surface 1211 of the light guide plate 121 and emit light to the light guide plate 121 through the light incidence surface 1211.

The lamp 131 may include a printed circuit board (PCB) 131a, an encapsulation member 131b, and a light emitting element 131c. The PCB 131a may be arranged on the side of the light guide plate 121 close to the side wall 111. The encapsulation member 131b may be arranged on a side of the PCB 131a close to the light guide plate 121 and connected to the PCB 131a. The encapsulation member 131b may define an encapsulation groove 1311. The light emitting element 131c may be adhered to the PCB 131a and may be received in the encapsulation groove 1311. The light emitting element 131c may emit the light to the light guide plate 121 through the encapsulation groove 1311. In some embodiments, the lamp 131 may include an array of light emitting elements 131c arranged on the PCB 131a along a row direction and a column direction. The PCB 131a may be arranged on the side of the light guide plate 121 close to the side wall 111. The row direction may be parallel to an extending direction of side of the light guide plate 121 arranged with the PCB 131a, and the column direction may be perpendicular to the row direction.

Alternatively, the light emitting element 131c may be an LED chip.

Further, the lamp 131 may be arranged at an optimized position for light emitting relative to the light guide plate 121.

The optimized position for light emitting may be a position of the lamp 131 from which the light emitted by the lamp 131 may be completely received by the light guide plate 121. The optimized position may be an optimized position in height and in distance. It may be understood that, when the lamp 131 is arranged at a position being too high or too low along a direction perpendicular to the bottom wall 112, the light guide plate 121 may be unable to receive the light emitted from the lamp 131 completely. When a distance between the lamp 131 and the light guide plate 121 is too long, the light emitted from the lamp 131 may escape from the light guide plate 121, and therefore, the light may not be completely received by the light guide plate 121, such that utilization of the light 131 and the backlight effect of the light guide plate 121 may be reduced.

Alternatively, the light emitting element 131c of the lamp 131 may be arranged on a central line of the light guide plate 121.

Alternatively, a first adhesion member 15 may be arranged between the lamp 131 and the bottom wall 112. The lamp 131 may be adhered to the bottom wall 112 via the first adhesion member 15, enabling the lamp 131 to be arranged at an optimized height relative to the light guide plate 121. That is, in the present embodiment, when the lamp 131 is adhered on the bottom wall 112 and fixed relative to the bottom wall 112 via the first adhesion member 15, a thickness of the first adhesion member 15 may be adjusted to enable the light emitting element 131c of the lamp 131 to be arranged at the optimized height relative to the light guide plate 121 (i.e., arranged to align with the central line of the light guide plate 121), such that utilization of the light source 131 and the backlight effect of the light guide plate 121 may be improved.

Alternatively, the first adhesion member 15 may be a double-sided tape.

Alternatively, a second adhesion member 16 may be arranged between the lamp 131 and the side wall 111. The lamp 131 may be adhered to the side wall 111 via the second adhesion member 16, enabling the lamp 131 to be arranged at an optimized distance relative to the light guide plate 121. That is, in the present embodiment, when the lamp 131 is adhered on the side wall 111 and fixed relative to the side wall 111 via the second adhesion member 16, a thickness of the second adhesion member 16 may be adjusted to enable the lamp 131 to be arranged at the optimized distance relative to the light guide plate 121, such that utilization of the light source 131 and the backlight effect of the light guide plate 121 may be improved.

As shown in FIG. 1, FIG. 2, and FIG. 3, the flexible circuit board 132 may be arranged to adhere to the lamp 131 on a side of the lamp 131 away from the light guide plate 121, such that a space for soldering the flexible circuit board 132 with the lamp 131 may not be required along a direction facing towards the side wall 111. Therefore, the space may be saved along a direction perpendicular to the side wall 111, a width of the backlight module 10 along the direction perpendicular to the side wall 111 may be reduced, and a narrow-sided backlight module maybe achieved.

Specifically, the flexible circuit board 132 may be adhered to a side of the PCB 131a away from the light emitting element 131c. As shown in FIG. 1, the flexible circuit board may extend through the opening 1111 to reach a side of the back frame 11 away from the receiving space 101.

The flexible circuit board 132 and the second adhesion member 15 may both be adhered to the PCB 131a.

The positioning member 14 may be connected to the back frame 11 and at least partially received in the receiving space 101.

Specifically, the positioning member 14 may include a body portion 14a and an extension portion 14b. The body portion 14a may be connected to the back frame 11. The extension portion 14b may extend from the body portion 14a towards the receiving space 101. In

FIG. 1, the body portion 14a may be at least partially received in the receiving space 101 and connect to the back frame 11. The extension portion 14b may extend from a part of the body portion 14a received in the receiving space 101.

Alternatively, the body portion 14a may be arranged at a position of which the at least two side walls 111 are bent and connected. The extension portion 14b may extend from the body portion 14a towards a position between the light guide plate 121 and at least one of the at least two side walls 111. In the present embodiment, the extension portion 14b may extend from the body portion 14a towards a position between the light guide plate 121 and one of the at least two side walls 111 without the backlight source 13. That is, the backlight source 13 may be arranged between a side of the light guide plate 121 and one of the at least two side walls 111, whereas the extension portion 14b may be arranged between another side of the light guide plate 121 and another one of the at least two side walls 111.

Alternatively, the positioning member 14 may be aligned with a side of the top wall 113 away from the receiving space 101, such that the positioning member 14 and the top wall 113 may cooperatively carry the display module of the electronic device. In the present embodiment, the body portion 14a may be aligned with the side of the top wall 113 away from the receiving space 101.

Further, the positioning member 14 may be arranged with a second positioning portion 141, and the second positioning portion 141 may be engaged with the first positioning portion 1213, such that the distance between the light guide plate 121 and the backlight source 13 may be less than or equal to a threshold.

It may be understood, during assembling the backlight module 10, the backlight source 13 may be disposed into the receiving space 101 of the back frame 11 firstly, and the optical assembly 12 may subsequently be disposed into the receiving space 101. At this point, an assembly gap may be reserved between the light guide plate 121 of the optical assembly 12 and the backlight source 13. That is, after disposing the optical assembly 12 into the receiving space 101, a gap may be defined between the light guide plate 121 and the backlight source 13. However, during an actual assembling process, after the optical assembly 12 being disposed into the receiving space 101, the gap between the light guide plate 121 and the backlight source 13 may be too large, such that the light guide plate 121 may not be able to receive the light emitted from the backlight source 13 completely, reducing the backlight effect of the light guide plate 121. In the present embodiment, the second positioning portion 141 of the positioning member 14 may be arranged to engage with the first positioning portion 1213 of the light guide portion 121. During engagement, the optical assembly 12 may disposed into the receiving space 101 by means of engaging the first positioning portion 1213 with the second positioning portion 141, such that the distance between the light guide plate 121 and the backlight source 13 is less than or equal to the threshold. A situation of the distance between the light guide plate 121 and the backlight source 13 being too long may be avoided during the assembling, assembly precision may be improved, and a difficulty of assembling may be reduced.

Alternatively, the second positioning portion 141 may be a protrusion engaged with the first positioning portion 1213 (such as the recess in the present embodiments), and a direction of the protrusion protruding towards the recess may be parallel to an extending direction of the backlight source 13. Specifically, the lamp 131 of the backlight source 13 may extend along the side of the light guide plate close to the side wall 111, and the second positioning portion 141 may perpendicularly protrude from an end of the extension portion 14b away from the body portion 14a. The protruding direction may be perpendicular to an extending direction of the extension portion 14b but parallel to the extending direction of the lamp 131. A side of the light guide plate 121 without the lamp 131 arranged may be recessed inwardly to define the recess, i.e., the first positioning portion 1213, and a direction of recessing may be parallel to the protruding direction of the second positioning portion 141. The protrusion may be in a shape of an arc, and the recess may also be in the shape of the arc. In such a way, the first positioning portion 141 may be engaged into the recess. In some embodiment, the lamp 131 may include an array of light emitting elements 131c arranged on the PCB 131a long a row direction and a column direction. The PCB 131a may be arranged on the side of the light guide plate 121 close to the side wall 111. The row direction may be parallel to an extending direction of side of the light guide plate 121 arranged with the PCB 131a, and the column direction may be perpendicular to the row direction. The protruding direction of the second positioning portion 141 may be parallel to the row direction.

Alternatively, the threshold may be less than or equal to 0.1 mm.

Further, in the present embodiment, the backlight module 10 may further include a light-shielding tape 17. The light-shielding tape 17 may be arranged on the side of the top wall 113 away from the receiving space 101 and may be adhered to the top wall 113 and the optical film assembly 122. In such a way, when the backlight source 13 is emitting light, and the light is transmitting through the light guide plate 121 to reach the optical film assembly 122, the light may not be escaped from the optical film assembly 122.

Specifically, the light-shielding tape 17 may be arranged on the side of the top wall 113 away from the receiving space 101, and may be adhered to the tope wall 113 and upper transmission increasing film 122c of the optical film assembly 122.

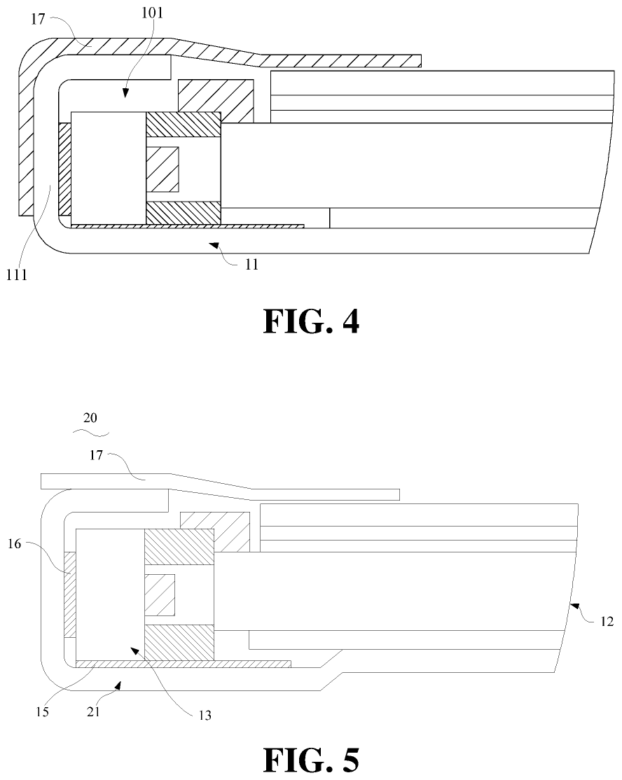

As shown in FIG. 4, in other embodiments, the light-shielding tape 17 may be adhered to a side of the side wall 111 away from the receiving space 101 to increase an adhesion area between the light-shielding tape 17 and the back frame 11, such that an adhesive force between the light-shielding tape 17 and the back frame 11 may be improved.

According to the backlight module provided in the present embodiment, the light guide plate may be arranged with the first positioning portion, and the positioning member may be arranged with the second positioning portion engaged with the first positioning portion, such that, during assembling the optical assembly, the first positioning portion and the second positioning portion may be engaged to achieve positioning, and the optical assembly may be disposed into the receiving space, such that the distance between the light guide plate and the backlight source may be less than or equal to the threshold. In such a way, during assembling, a situation of the distance between the light guide plate and the backlight source being too long may be avoided, and the light guide plate unable to completely receive the light emitted from the backlight source may be avoided, improving the backlight effect of the light guide plate, improving the assembly accuracy, and reducing the difficulty of assembling.

As shown in FIG. 5, a cross-sectional view of the backlight module 20 according to the second embodiment is provided. The backlight module 20 may include a back frame 21, an optical assembly 12, a backlight source 13, and a positioning member 14.

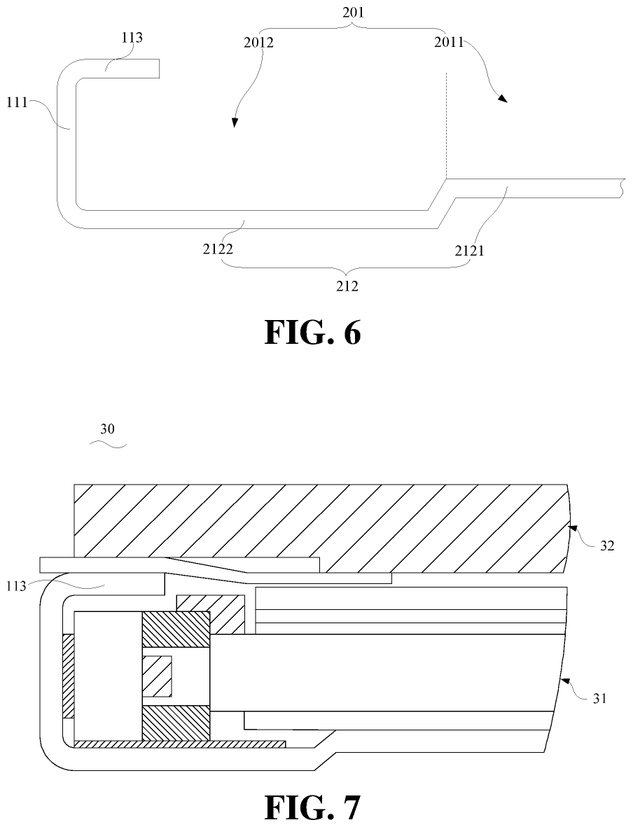

As shown in FIG. 5 and FIG. 6, the back frame 21 may include a side wall 111 and a bottom wall 212. The side wall 111 and the bottom wall 212 may be bent and connected to each other to define a receiving space 201.

Alternatively, at least two the side walls 111 may be arranged, and the at least two side walls 111 may be bent and connected to each other.

Alternatively, the back frame 21 may further include a top wall 113, and the top wall 113 and an end of the side wall 111 away from the bottom wall 212 may be bent and connected to each other. The top wall 113, the side wall 111, and the bottom wall 212 may cooperatively define the receiving space 201. The top wall 113 may be arranged to support a display module while assembling the backlight module 10 with the display module of the electronic device.

The receiving space 201 may include a first space 2011 and a second space 2012 communicating with each other, and the first space 2011 and the second space 2012 may be defined sequentially along a direction facing towards the side wall 111. An area of a cross section of the second space 2012 taken along a direction facing the side wall 111 is greater than that of the first space 2011 taken along a direction facing the side wall 111.

Specifically, the bottom wall 212 may include a first bottom wall 2121 and a second bottom wall 2122. The first bottom wall 2121 and the second bottom wall 2122 are connected to each other and arranged sequentially along a direction facing towards the side wall 111. As shown in FIG. 6, a vertical distance between the second bottom wall 2122 and the top wall 113 may be greater than a vertical distance between the first bottom wall 2121 and the top wall 113. In such a way, when the receiving space 201 is defined, cross sections of the first and the second spaces may be taken along the direction facing towards the side wall 111, the area of the cross section of the second space 2012 defined by the second side wall 2122 may be greater than that of the first space 2011 defined by the first side wall 2121.

Further, the back frame 21 may define an opening 1111 communicating with the receiving space 201.

Alternatively, the back frame 21 may be a metal back frame.

The optical assembly 12 may be received in the receiving space 201 and may be arranged on the bottom wall 212.

Specifically, the optical assembly 12 may be received in the first space 2011 of the receiving space 201.

The optical assembly 12 may include a light guide plate 121. The light guide plate 121 may include a light incidence surface 1211 and a light emitting surface 1212. The light incidence surface 1211 may be a side of the light guide plate 121 close to the side wall 111, and the light emitting surface 1212 may be a side of the light guide plate 121 away from the bottom wall 212. Further, the light guide plate 121 may be arranged with a first positioning portion 1213.

Alternatively, the first positioning portion may be a recess.

Further, the optical assembly 12 may further include an optical film assembly 122 and a reflection sheet 123. The optical film assembly 122 may be arranged on the light guide plate 121 and may specifically be on the light emitting surface 1212 of the light guide plate 121. The reflection sheet 123 may be arranged on the bottom wall 212 facing towards a side of the light guide plate 121 away from the light emitting surface 1212.

The optical film assembly 122 may include a diffusion film 122a, a lower transmission increasing film 122b, and an upper transmission increasing film 122c sequentially stacked along a direction away from the light guide plate 121.

The backlight source 13 may be arranged on the side of the light guide plate 121 close to the side wall 111. Specifically, the backlight source 13 may be arranged on the side of the light guide plate 121 close to one of the at least two side walls 111.

The backlight source 13 may include a lamp 131 and a flexible circuit board 132.

The lamp 131 may be arranged on the side of the light guide plate 121 close to the side wall 111. Specifically, the lamp 131 may be arranged on the light incidence surface 1211 of the light guide plate 121 to emit light to the light guide plate 121 through the light incidence surface 1211.

Further, the light source 131 may be received in the second space 2012.

The lamp 131 may include a PCB 131a, an encapsulation member 131b, and a light emitting element 131c. The PCB 131a may be arranged on the side of the light guide plate 121 close to the side wall 111. The encapsulation member 131b may be arranged on a side of the PCB 131a close to the light guide plate 121 and connected to the PCB 131a. The encapsulation member 131b may define an encapsulation groove 1311. The light emitting element 131c may be adhered to the PCB 131a and may be received in the encapsulation groove 1311. The light emitting element 131c may emit the light to the light guide plate 121 through the encapsulation groove 1311.

Alternatively, the light emitting element 131c may be an LED chip.

Further, the lamp 131 may be arranged at an optimized position for light emitting relative to the light guide plate 121.

The optimized position for light emitting may be a position of the lamp 131 from which the light emitted may be completely received by the guide plate 121. The optimized position may be an optimized position in height and in distance. It may be understood that, when the lamp 131 is arranged at a position being too high or too low along a direction perpendicular to the bottom wall 212, the light guide plate 121 may be unable to receive the light emitted from the lamp 131 completely. When a distance between the lamp 131 and the light guide plate 121 is too long, the light emitted from the lamp 131 may escape from the light guide plate 121, and therefore, the light may not be completely received by the light guide plate 121, such that utilization of the light source 131 and the backlight effect of the light guide plate 121 may be reduced.

Alternatively, the light emitting element 131c of the lamp 131 may be arranged on a central line of the light guide plate 121.

Alternatively, a first adhesion member 15 may be arranged between the lamp 131 and the bottom wall 212. The lamp 131 may be adhered to the bottom wall 212 via the first adhesion member 15, enabling the lamp 131 to be arranged at the optimized position in height relative to the light guide plate 121. That is, in the present embodiment, when the lamp 131 is adhered on the bottom wall 212 and fixed relative to the bottom wall 212 via the first adhesion member 15, a thickness of the first adhesion member 15 may be adjusted to enable the lamp 131 to be arranged at the optimized position in height relative to the light guide plate 121, such that utilization of the light source 131 and the backlight effect of the light guide plate 121 may be improved.

Further, as the light 131 may be received in the second space 2012, and the area of the cross section of the second space 2012 taken along the direction perpendicular to the side wall 111 is greater than that of the first space 2011 taken along the direction perpendicular to the side wall 111, when a height of the light 131 relative to the light guide plate 121 is adjusted, an enough space for adjustment may be defined. A situation of defining insufficient space for adjustment may be avoided. When the space for adjustment is insufficient, a thickness of the first adhesion member 15 may be reduced, a small thickness of the first adhesion member 15 may reduce an adhesive force between the light 131 and the bottom wall 212. Alternatively, under such the situation of insufficient space for adjustment, the light 131 may not be arranged at the optimized position to prevent the thickness of the first adhesion member 15 from being too small, reducing the backlight effect of the light guide plate 121.

Alternatively, the first adhesion member 15 may be a double-sided tape.

Alternatively, a second adhesion member 16 may be arranged between the lamp 131 and the side wall 111. The lamp 131 may be adhered to the side wall 111 via the second adhesion member 16, enabling the lamp 131 to be arranged at the optimized position in distance relative to the light guide plate 121. That is, in the present embodiment, when the lamp 131 is adhered on the side wall 111 and fixed relative to the side wall 111 via the second adhesion member 16, a thickness of the second adhesion member 16 may be adjusted to enable the lamp 131 to be arranged at the optimized distance relative to the light guide plate 121, such that utilization of the light 131 and the backlight effect of the light guide plate 121 may be improved.

The flexible circuit board 132 may be arranged to adhere to a side of the lamp 131 away from the light guide plate 121, such that a space for soldering the flexible circuit board 132 with the lamp 131 may not be required along a direction facing towards the side wall 111. Therefore, the space may be saved along the direction perpendicular to the side wall 111, a width of the backlight module 10 along the direction perpendicular to the side wall 111 may be reduced, and the backlight module having a narrow side maybe achieved.

Specifically, the flexible circuit board 132 may be adhered to a side of the PCB 131a away from the light emitting element 131c. The flexible circuit board may extend through the opening 1111 to reach a side of the back frame 11 away from the receiving space 101.

The flexible circuit board 132 and the second adhesion member 15 may both be adhered to the PCB 131a.

The positioning member 14 may be connected to the back frame 11 and at least partially received in the receiving space 201.

Specifically, the positioning member 14 may include a body portion 14a and an extension portion 14b. The body portion 14a may be connected to the back frame 11. The extension portion 14b may extend from the body portion 14a towards the receiving space 201. The positioning member 14 in the second embodiment is similar to that in the first embodiment, and by referring to FIG. 1, the body portion 14a may be at least partially received in the receiving space 201 and may connect to the back frame 11. The extension portion 14b may extend from a part of the body portion 14a received in the receiving space 201.

Alternatively, the body portion 14a may be arranged at a position of which the at least two side walls 111 are bent and connected. The extension portion 14b may extend from the body portion 14a towards a position between the light guide plate 121 and at least one of the at least two side walls 111. In the present embodiment, the extension portion 14b may extend from the body portion 14a towards a position between the light guide plate 121 and one of the at least two side walls 111 without the backlight source 13. That is, the backlight source 13 may be arranged between a side of the light guide plate 121 and one of the at least two side walls 111, whereas the extension portion 14b may be arranged between another side of the light guide plate 121 and another one of the at least two side walls 111.

Alternatively, the positioning member 14 may be aligned with the side of the top wall 113 away from the receiving space 201, such that the positioning member 14 and the top wall 113 may cooperatively carry the display module of the electronic device. In the present embodiment, the body portion 14a may be aligned with the side of the top wall 113 away from the receiving space 201.

Further, the positioning member 14 may be arranged with a second positioning portion 141, and the second positioning portion 141 may be engaged with the first positioning portion 1213, such that the distance between the light guide plate 121 and the backlight source 13 may be less than or equal to a threshold.

It may be understood, during assembling the backlight module 10, the backlight 13 may be disposed into the receiving space 201 of the back frame 11 first, and the optical assembly 12 may subsequently be disposed into the receiving space 201. At this point, an assembly gap may be reserved between the light guide plate 121 of the optical assembly 12 and the backlight 13. That is, after disposing the optical assembly 12 into the receiving space 201, a gap may be defined between the light guide plate 121 and the backlight source 13. However, during an actual assembling process, after the optical assembly 12 being disposed into the receiving space 201, the gap between the light guide plate 121 and the backlight 13 may be too large, such that the light guide plate 121 may not be able to receive the light emitted from the backlight source 13 completely, reducing the backlight effect of the light guide plate 121. In the present embodiment, the second positioning portion 141 of the positioning member 14 may be arranged to engage with the first positioning portion 1213 of the light guide portion 121. During engagement, the optical assembly 12 may disposed into the receiving space 101 by means of engaging the first positioning portion 1213 with the second positioning portion 141, such that the distance between the light guide plate 121 and the backlight source 13 is less than or equal to the threshold. A situation of the distance between the light guide plate 121 and the backlight source 13 being too long may be avoided during the assembling, assembly precision may be improved, and a difficulty of assembling may be reduced.

Alternatively, the second positioning portion 141 may be a protrusion engaged with the recess of the first positioning portion 1213, and a direction the protrusion protruding towards the recess may be parallel to an extending direction of the backlight source 13. Specifically, the lamp 131 of the backlight source 13 may extend along the side of the light guide plate close to the side wall 111, and the second positioning portion 141 may perpendicularly protrude from an end of the extension portion 14b away from the body portion 14a. The protruding direction may be perpendicular to an extending direction of the extension portion 14b but parallel to the extending direction of the lamp 131. A side of the light guide plate 121 without the lamp 131 arranged may be recessed inwardly to define the recess, i.e., the first positioning portion 1213, and a direction of recessing may be parallel to the protruding direction of the second positioning portion 141. The protrusion may be in a shape of an arc, and the recess may also be in the shape of the arc. In such a way, the first positioning portion 141 may be engaged into the recess.

Alternatively, the threshold may be less than or equal to 0.1 mm.

Further, in the present embodiment, the backlight module 20 may further include a light-shielding tape 17. The light-shielding tape 17 may be arranged on the side of the top wall 113 away from the receiving space 201 and may be adhered to the top wall 113 and the optical film assembly 122. In such a way, when backlight source 13 is emitting light, and the light is transmitting through the light guide plate 121 reaching the optical film assembly 122, the light may not be escaped from the optical film assembly 122.

Specifically, the light-shielding tape 17 may be arranged on the side of the top wall 113 away from the receiving space 201, and may be adhered to the tope wall 113 and upper transmission increasing film 122c of the optical film assembly 12.

Alternatively, in other embodiments, the light-shielding tape 17 may be adhered to a side of the side wall 111 away from the receiving space 201 to increase an adhesion area between the light-shielding tape 17 and the back frame 11, such that an adhesive force between the light-shielding tape 17 and the back frame 11 may be improved.

According to the backlight module provided in the present embodiment, the light guide plate may be arranged with the first positioning portion, and the positioning member may be arranged with the second positioning portion engaged with the first positioning portion, such that, during assembling the optical assembly, the first positioning portion and the second positioning portion may be engaged to achieve positioning. The optical assembly may be disposed into the receiving space, such that the distance between the light guide plate and the backlight source may be less than or equal to the threshold. In such a way, during assembling, a situation of the distance between the light guide plate and the backlight source being too long may be avoided, and the light guide plate unable to receive the light emitted from the backlight source may be avoided, improving the backlight effect of the light guide plate, improving the assembly accuracy, and reducing the difficulty of assembling. Further, the lamp may be disposed in the second space, the area of the cross section of the second space taken along the direction facing towards the side wall is greater than that of the first space taken along the direction facing towards the side wall. When the height of the lamp relative to the bottom wall is adjusted, sufficient space may be defined. A situation of insufficient space for adjustment may be avoided, and reducing the thickness of the first adhesion member resulting in reduction of the adhesive force between the lamp and the bottom wall may be prevented. Alternatively, a situation of arranging the adhesion member in a proper thickness but resulting in the lamp missing the optimized position in height and reducing the backlight effect may be prevented.

As shown in FIG. 7, a structural diagram of an electronic device 30 is provided according to an embodiment. The electronic device in the present embodiment may be any device having functions of communication and storage, such as a tablet computer, a mobile phone, an electronic reader, a network television, a wearable device, and other intelligent devices able to connect to the network.

The electronic device 30 may include the backlight module 31 as described in any one of the above-mentioned embodiments and a display module 32. The backlight module 31 may refer to detailed description of any one of the above-mentioned embodiments, and will not be repeatedly described hereinafter. The backlight module 20 described in the second embodiment may be shown in the figure of the present embodiment.

The display module 32 may be arranged to stack above the backlight module 31.

Further, the display module 32 may be carried by the top wall 113.

Only a part of embodiments are described in the above, and should not limit the scope of the present disclosure. Any equivalent apparatus and equivalent process transformation based on the drawings and the specification of the present disclosure, applied directly or indirectly in other related art, should be within the scope of the present disclosure.

What is claimed is:

1. A backlight module, comprising:
a back frame, comprising a side wall and a bottom wall, wherein the side wall and the bottom wall are connected to each other and define a receiving space;
an optical assembly, arranged on the bottom wall and received in the receiving space, wherein the optical assembly comprises a light guide plate, and the light guide plate defines a recess;
a backlight source, comprising an array of light emitting elements and a flexible circuit board, wherein the light emitting elements are arranged on a side of the light guide plate close to the side wall and has a row direction parallel to an extending direction of the side of the light guide plate arranged with the light emitting elements; and
a positioning member, arranged to connect to the back frame and at least partially received in the receiving space, wherein the positioning member comprises a positioning portion engaged in the recess such that a distance between the light guide plate and the backlight source is less than or equal to a threshold;
wherein the positioning portion is arranged to protrude from the positioning member, and a protruding direction of the positioning portion is parallel to the row direction of the light emitting elements.

2. The backlight module according to claim 1, wherein the positioning member further comprises a body portion and an extension portion, the body portion is connected to the back frame, and the extension portion is arranged to extend from the body portion towards the receiving space, and the positioning portion is arranged to perpendicularly protrude from an end the extension portion away from the body portion.

3. The backlight module according to claim 2, wherein at least two side walls are arranged, the at least two side walls are connected to each other, the body portion is arranged at a position at which the at least two side walls connect to each other, and the extension portion is arranged to extend from the body portion towards a position between another side of the light guide plate without the backlight source arranged and at least one of the at least two side walls.

4. A backlight module, comprising:
a back frame, comprising a side wall and a bottom wall, wherein the side wall and the bottom wall are connected to each other and define a receiving space;
an optical assembly, arranged on the bottom wall and received in the receiving space, wherein the optical assembly comprises a light guide plate, and the light guide plate defines a recess;
a backlight source, comprising a lamp and a flexible circuit board, wherein the lamp is arranged on and extend along a side of the light guide plate close to the side wall; and
a positioning member, arranged to connect to the back frame and at least partially received in the receiving space, wherein the positioning member comprises a positioning portion, the positioning portion is engaged into the recess, and an extending direction of the positioning portion is parallel to an extending direction of the lamp, such that a distance between the light guide plate and the backlight source is less than or equal to a threshold.

5. The backlight module according to claim 4, wherein the positioning member further comprises a body portion and an extension portion, the body portion is arranged to connect to the back frame, the extension portion is arranged to extend from the body portion towards the receiving space, and the positioning portion is arranged on the extension portion.

6. The backlight module according to claim 5, wherein at least two side walls are arranged, the at least two side walls are connected to each other, the body portion is arranged at a position at which the at least two side walls are connected to each other, and the extension portion is arranged to extend from the body portion towards a position between the light guide plate and at least one of the at least two side walls.

7. The backlight module according to claim 5, wherein the lamp is a plurality of light emitting elements arranged in a row, the positioning portion is arranged to perpendicularly protrude from an end of the extension portion away from the body portion, and a protruding direction of the positioning portion is parallel to a direction of the row.

8. The backlight module according to claim 4, wherein
the back frame further comprises a top wall;
the top wall and an end of the side wall away from the bottom wall are connected to each other;
the top wall, the side wall, and the bottom wall cooperatively define the receiving space; and
the positioning member is arranged on a side of the top wall away from the receiving space and is arranged to align with the top wall.

9. The backlight module according to claim 4, wherein the threshold is less than or equal to 0.1 mm.

10. The backlight module according to claim 4, wherein the flexible circuit board is adhered to a side of the lamp away from the light guide plate.

11. The backlight module according to claim 10, wherein the light guide plate comprises a light incidence surface and a light emitting surface, the lamp is arranged on the light incidence surface of the light guide plate and at an optimized position for light emitting.

12. The backlight module according to claim 11, wherein the optimized position for light emitting is an optimized position of the lamp in height and in distance relative to the light guide plate, enabling emitted light to be completely received by the light guide plate.

13. The backlight module according to claim 12, wherein a first adhesion member is arranged between the lamp and the bottom wall, and the lamp is adhered to the bottom wall via the first adhesion member, such that the lamp is arranged at the optimized position in height relative to the light guide plate by providing the first adhesion member in an appropriate thickness.

14. The backlight module according to claim 12, wherein a second adhesion member is arranged between the lamp and the side wall, and the lamp is adhered to the side wall via the second adhesion member, such that the lamp is arranged at the optimized position in distance relative to the light guide plate by providing the second adhesion member in an appropriate thickness.

15. The backlight module according to claim 10, wherein the receiving space comprises a first space and a second space communicating with each other, the first space and the second space are sequentially defined along a direction facing towards the side wall, the optical assembly is received in the first space, an area of a cross section of the second space taken along the direction facing towards the side wall is greater than that of the first space taken along the facing towards the side wall, and the lamp is received in the second space.

16. The backlight module according to claim 8, wherein the optical assembly further comprises an optical film assembly arranged on a light emitting surface of the light guide plate, the backlight module further comprises a light-shielding tape, and the light-shielding tape is arranged on a side of the top wall away from the receiving space and adhered to the top wall and the optical film assembly.

17. The backlight module according to claim 16, wherein the light-shielding tape is further arranged on a side of the side wall away from the receiving space and adhered to the side wall.

18. An electronic device, comprising a display module and a backlight module, wherein the display module is arranged to stack above the backlight module, and the backlight module comprises:
a back frame, comprising a side wall and a bottom wall, wherein the side wall and the bottom wall are connected to each other and define a receiving space;
an optical assembly, arranged on the bottom wall and received in the receiving space, wherein the optical assembly comprises a light guide plate, and the light guide plate defines a recess;
a backlight source, arranged on a side of the light guide plate close to the side wall; and
a positioning member, arranged to connect to the back frame and at least partially received in the receiving space, wherein the positioning member comprises a positioning portion,
the positioning portion is engaged into the recess, such that a distance between the light guide plate and the backlight source is less than or equal to a threshold, wherein the threshold is less than or equal to 0.1 mm.

19. The electronic device according to claim 18, wherein the positioning member further comprises a body portion and an extension portion, the body portion is connected to the back frame, and the extension portion is arranged to extend from the body portion towards a position between another side of the light guide plate without the backlight source arranged and the side wall.

20. The electronic device according to claim 19, wherein the backlight source comprises a lamp extending along the side of the light guide plate close to the side wall, the positioning portion is arranged to perpendicularly protrude from an end of the extension portion away from the body portion, and a protruding direction of the positioning portion is parallel to an extending direction of the lamp.
